(19) United States
(12) Patent Application Publication
(10) Pub. No.: US 2026/0298976 A1
(43) Pub. Date: Oct. 1, 2026

(54) HIGH TEMPERATURE AND HIGH CURRENT NON-ZERO INSERTION FORCE SPRING CONTACT RECEPTACLE FOR DUT SOCKETS

(71) Applicant: QualiTau, Inc., Santa Clara, CA (US)

(72) Inventors: Adalberto M. RAMIREZ, Hayward, CA (US); Mirtcha LUPASHKU, Sutter Creek, CA (US); David Ferdinand VANDENBERG, San Rafael, CA (US); Leslie Roy GRATE, Santa Cruz, CA (US); Yuqi WANG, San Jose, CA (US); Jorge Rubén SARELLANO ROBLES, Manteca, CA (US)

(21) Appl. No.: 19/092,942

(22) Filed: Mar. 27, 2025

(51) Int. Cl. G01R 1/04

(52) U.S. Cl. CPC G01R 1/0466

(57) ABSTRACT

A test socket assembly, able to operate reliably at temperatures greater than 350° C. and at test currents greater than 1 amp DC per pin, for use in testing a packaged integrated circuit device having a plurality of pins extending therefrom. The test socket assembly includes a plurality of one-piece spring contact receptacles and a plurality of compression springs. Each of the one-piece spring contact receptacles is positioned under an opening to receive a pin extending from the test package and each of the one-piece spring contact receptacles is positioned over at least one compression spring.

### FIELD OF INVENTION

The present invention relates generally to the testing of electrical integrated circuits (IC), and more particularly to sockets for receiving packaged integrated circuits for test purposes.

### BACKGROUND

Conventional high temperature and high-test-current test methods primarily include zero insertion force (ZIF) sockets based on perpendicularly placed contact wires which flex when test device pins are pressed laterally against them and non-ZIF sockets based on readily available contact pin receptacles installed over compression (helical coil) springs. Currently there is no test socket solution that can simultaneously and reliably operate with test currents above 1 amp DC per pin (direct current (DC) with a current flow at 1 amp), at temperatures above 350° C., and that can maximize the device under test (DUT) board capacity with multiple test devices (packages). All presently available solutions have at least one or more such restrictions.

### SUMMARY

In accordance with an embodiment, a test socket assembly is provided for use in testing a packaged integrated circuit device having a plurality of pins extending therefrom. The test socket assembly includes a first member and a plurality of one-piece spring contact receptacles. The first member receives an integrated circuit test package and having a plurality of openings for receiving pins extending from the test package. Each of the one-piece spring contact receptacles is positioned under an opening to receive a pin extending from the test package.

In accordance with another embodiment, a test socket assembly is disclosed for use in testing a packaged integrated circuit device having a plurality of pins extending therefrom. The test socket assembly includes a first member for receiving an integrated circuit test package, a second member stacked below the first member, a third member stacked below the second member, a plurality of one-piece spring contact receptacles, and a plurality of compression springs. The first member has a plurality of openings configured to receive pins extending from the test package. Each of the one-piece spring contact receptacles is positioned in the second member under an opening of the first member to receive a pin extending from the test package. Each of the one-piece spring contact receptacles is positioned over at least one compression spring, and each of the compression springs is positioned in the third member. The test socket assembly can operate reliably at temperatures greater than 350° C. and at test currents greater than 1 amp DC per pin.

### BRIEF DESCRIPTION OF THE DRAWINGS

The invention, together with further objects and advantages thereof, may best be understood by reference to the following description taken in conjunction with the accompanying drawings in which:

FIG. 1 is a perspective view of an exemplary Ceramic Dual Inline Package (CERDIP).

FIG. 2 is a perspective view of an exemplary SIDEBRAZE Dual Inline Package.

FIG. 3 is a side view of a traditional aluminum non-ZIF socket having three plates.

FIG. 4 is a side view of a traditional one-piece ceramic body non-ZIF socket.

FIG. 5 is a top perspective view of a traditional non-ZIF socket.

FIGS. 6 and 7 show traditional ceramic ZIF sockets.

FIG. 8A is a perspective view of an embodiment of a spring contact receptacle.

FIG. 8B is a front view of the embodiment of the spring contact receptacle shown in FIG. 8A.

FIG. 8C is a side view of the embodiment of the spring contact receptacle shown in FIGS. 8A and 8B.

FIG. 9A is a perspective view of an embodiment of a middle socket plate.

FIG. 9B is a perspective view of an embodiment of a top socket plate.

FIG. 9C is a perspective view of an embodiment of a bottom socket plate.

FIG. 9D is a perspective of another embodiment of a bottom socket plate.

FIG. 10 shows a cut-out view of an embodiment of a test socket assembly.

FIG. 11 shows a cut-out view of another embodiment of a test socket assembly.

FIG. 12 is a perspective view of the test socket assembly with a CERDIP test package inserted.

FIG. 13 is a perspective view of the test socket assembly shown in FIG. 12 with a SIDEBRAZE test package inserted.

FIG. 14 is a perspective view of an embodiment of a DUT board with multiple test socket assemblies and multiple nut plates attached.

### DETAILED DESCRIPTION

The present invention relates generally to test sockets for receiving packaged integrated circuits for test purposes. The embodiments herein describe test sockets that allow for testing of packaged integrated circuits at high temperatures (greater than 350° C.) and at high currents (greater than 1 amp per pin).

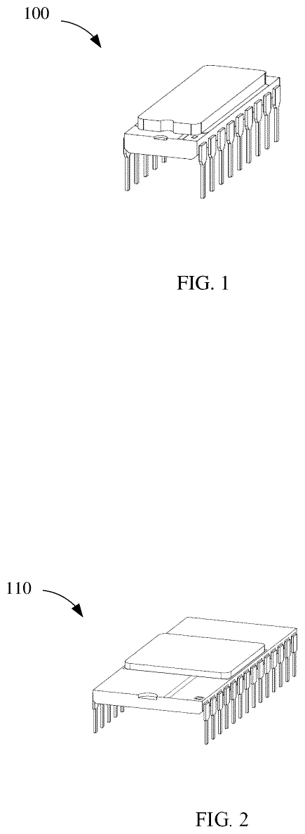

IC test devices (packages) are typically housed in packages, such as a Ceramic Dual Inline Package (CERDIP) 100 or SIDEBRAZE Dual Inline Package (DIP) 110, as shown in FIGS. 1 and 2. Common end-use applications include device characterization, reliability, electromigration, environmental, and burn-in testing. Common DIP packages consist of two rows of pins (electrical contacts) which are 0.3″ or 0.6″ apart and with a 0.1″ pitch (pin to pin distance).

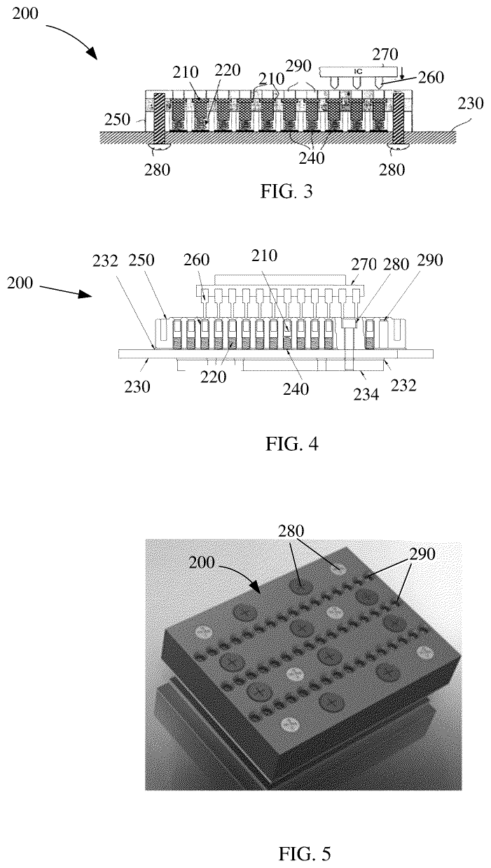

For high temperature (and high test current) applications (beyond the limits of eutectic solder alloys and phenolic printed circuit board (PCB) technologies limited to about 250° C.), the conventional methods for connecting test device package pins (leads) to the metallic conductors (pads) on a device under test (DUT) board or PCB include traditional non-ZIF sockets and ceramic ZIF sockets. FIGS. 3-5 show traditional non-ZIF sockets 200 built using a combination of readily available contact pin receptacles 210 installed over compression (helical coil) springs 220. The sockets' body 250 is generally constructed from non-electrically conductive ceramic or anodized aluminum. The electrical connection from the contact pin receptacles 210 to high temperature gold pads 240 on the PCB 230 is made through compression springs 220, as shown in FIGS. 3 and 4. The compression springs 220 counteract the thermal expansion and contraction forces and mechanical tolerances resulting from involved parts and materials. It will be understood that it is not practical to solder or braze a direct strong bond from the contact pin receptacle 210 to surface-mount-technology (SMT) pads 240 on a DUT board 230 due to physical constraints and temperature conditions; the surface of the SMT pad 240 is too thin and fragile for soldering or brazing, the surface area of the contact pin receptacle 210 is too small to create a strong bond between the contact pin receptacle 210 and the SMT pad 240, and the available soldering and brazing materials and methods cannot meet the high temperature requirements of the test socket 200. Screws 280 hold socket plates together to form the socket body 250. The embodiment of FIG. 4 also shows a mica insulator 232 on both sides of the DUT board 230 between the DUT board 230 and the socket body 250 and between the DUT board 230 and a nut plate 234.

The leads or pins 260 of a test package 270 are inserted through openings 290 in the top surface of the body 250 of the socket 200, as shown in FIGS. 3 and 4. The connection to the pin (lead) 260 of the test package 270 is made inside the contact pin receptacle 210 through small beryllium nickel springs or clips (not shown), which press laterally against the test package pin 260. These connections must remain electrically stable at temperature and for extended periods of time. During its lifetime, a DUT board and test socket are expected to last several months or a few years in operation, while enduring several temperature ramp ups and ramp downs and test package replacement cycles (typically about 5-20 cycles per year). The socket's internal electrical components (contact pin receptacles 210 and springs 220) can degrade prematurely due to heavy oxidation resulting from exposure to high temperature and internal joule heat. The spring clips inside the contact pin receptacles 210 lose their spring function at temperatures above 350° C., thus limiting the socket's maximum reliable usage to temperatures below 350° C. The shell body of the contact pin receptacle 210 is typically made of brass alloy and is electro-plated with gold over nickel. Unfortunately, the outer shell body of the contact pin receptacle 210 will rapidly deteriorate at high temperatures (temperatures greater than about 350° C.) and thus result in poor contact to the compression spring 220.

Unless all internal electrical components (contact pin receptacles 210 and springs 220) of the socket 200 are periodically replaced, this traditional non-ZIF socket design is unreliable at high temperatures for extended periods of time (over one year with typical usage). Periodic replacement of contact pin receptacles and springs is not only costly but also time consuming. Further, such replacement of contact pin receptacles and springs may potentially compromise the integrity of the test DUT boards. This socket design is also limited to 1 amp DC maximum test current, primarily due to the physical limitations of the single compression spring located under each contact pin receptacle.

Brazing or welding is an alternative method of making a connection between the contact pin receptacles and SMT pads. However, brazing or welding socket pin receptacles 210 to the main PCB 230 is only possible for certain applications and only if the PCB 230 is of a through-hole type. For temperatures above 250° C., conventional phenolic PCBs cannot be used, mostly for two reasons: The phenolic PCBs are generally rated to about 250° C. absolute maximum temperature, and no conventional solders can be used at those temperatures to “solder” any connectors, pin contact receptacles, springs, wires, etc. onto a thick-film based ceramic coated PCB board. Boards designed for super high temperatures (beyond the limits of phenolic materials at about 250° C. or higher) are generally not through-hole type boards due to their metallic core and therefore SMT flat pads 240 are used instead and are generally of screen-printed materials (gold or silver-based materials) as opposed to etched from solid copper laminates. The screen-printed materials are generally thin and fragile. Also, using other methods such as brazing, welding, etc. is not possible or practical due to the small physical geometries involved, and because thick-film based PCBs have very thin and fragile conductors and contact pads.

Brazing or welding anything to the screen-printed materials is simply not possible or mechanically sound and is also difficult due to the small surrounding area (pitch) between the contact pin receptacles 210. Compression springs are generally necessary for applications greater than 250° C., where traditional soldering or brazing methods are not possible.

At high temperatures (temperatures greater than 350° C.), accelerated oxidation of the contact pin receptacles is a problem due to the material properties of the contact pin receptacles. As noted above, the outer shell of a contact pin receptacle is generally made of brass alloy and electro-plated with gold over nickel. Other materials, including beryllium-copper, tellurium copper, and phosphor-bronze, and different combinations of electro-plating formulations with such materials, do not resolve accelerated oxidation issues of the pin receptacles. The contact pin receptacles' internal spring clips (generally made from beryllium nickel) also deteriorate rapidly at temperatures beyond 350° C. and such deterioration, in turn, causes electrical failures. The cylindrical shape of the contact pin receptacles further compromises the reliability of the electrical connection to the IC test package pins and to the coiled spring below, due to the unintended movement and rotation caused by insertion and extraction of IC test packages. This action may cause the pin receptacle contact areas to break loose from previously good areas and reposition to poorly conductive or oxidized areas. For example, it is well known that, at elevated temperatures (over 350° C.), nickel oxidation is highly accelerated and beryllium nickel spring properties degrade rapidly at temperatures over 350° C.

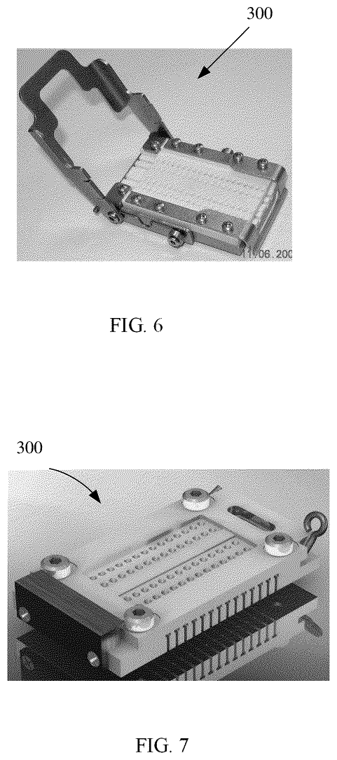

An alternative conventional socket option for testing IC packages is a ceramic ZIF socket 300, as shown in FIGS. 6 and 7. The body of the ceramic ZIF socket 300 is generally constructed from solid ceramic parts. The advantages of a ceramic ZIF socket design are that its construction is simpler with fewer components than that of a non-ZIF socket, and the ZIF sockets 300 are easy to operate because no force is required to insert and extract IC test packages. However, these ceramic ZIF sockets 300 are also more expensive to manufacture, are bulky (preventing their use in many applications requiring high test DUT density), and have a safe test current limit of about 1 amp per pin, mainly due to the single lateral electrical contact point limited to the radius of the wire pressing against the test package pin (the contact area between round wire and the test package pin is minimal).

Such ceramic ZIF sockets 300 are typically rated at 350° C.; if such sockets are operated at temperatures as high as 400° C., the sockets will have higher failure rates and a reduced lifetime. In ZIF sockets, a round spring contact wire is pressed laterally against the test package pin and the round contact wire's movement and rotation (each time a test device is loaded or removed from the socket) might cause contact breakage at the pads of the DUT board. This design requires the contact spring (formed round wire) to make a single-point contact to the board's fragile SMT pads using mechanical pressure. This pressure, while the socket is at high temperatures over extended periods (several days to weeks) of time, might “fuse” or “bond” the contact wire to the pad and may cause irreparable damage to the SMT pads if the socket needs to be disassembled for repairs.

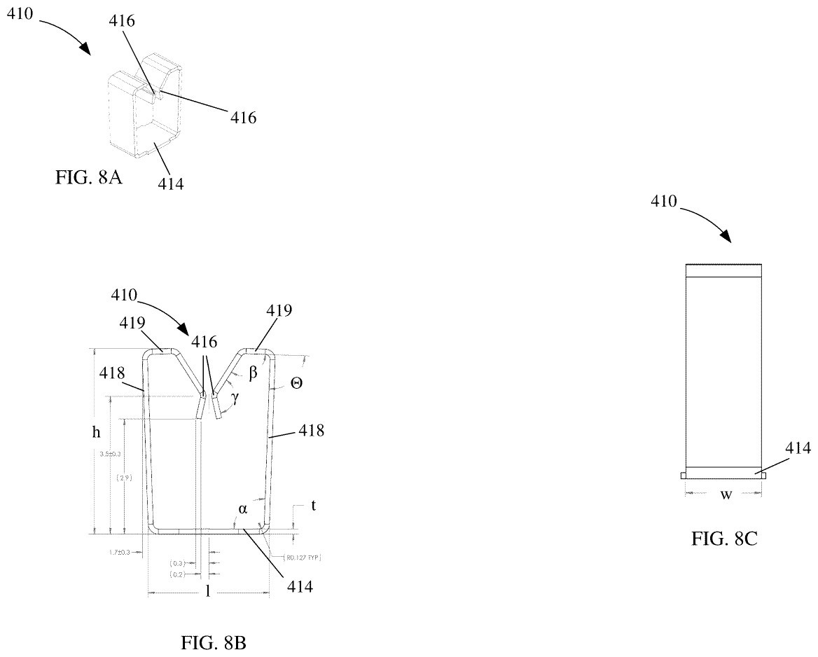

Embodiments of high temperature, high current non-ZIF spring receptacles for test sockets are described herein with reference to FIGS. 8A-14. These embodiments take a different approach to contact receptacles and socket design by addressing the various physical and electrical limitations of traditional non-ZIF and ZIF sockets as described above. Spring receptacle sockets described herein provide a reliable test socket for testing conventional CERDIP or SIDEBRAZE DIP packages. These packages have two rows of pins (typically 0.300″ or 0.600″ apart) and with pins typically spaced by 0.1″ (pitch). As described in more detail below, according to an embodiment shown in FIGS. 8A-8C, a spring contact receptacle 410 for a test socket assembly 400 provides increased electrical contact while minimizing electrical resistance as compared to a pin contact receptacle 210 in a conventional non-ZIF and ZIF sockets.

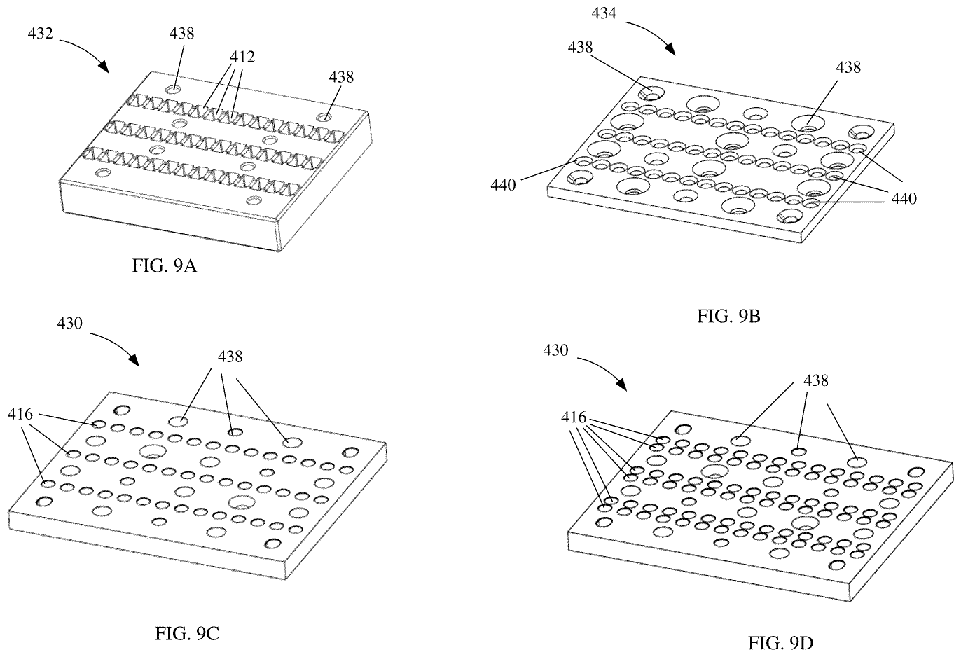

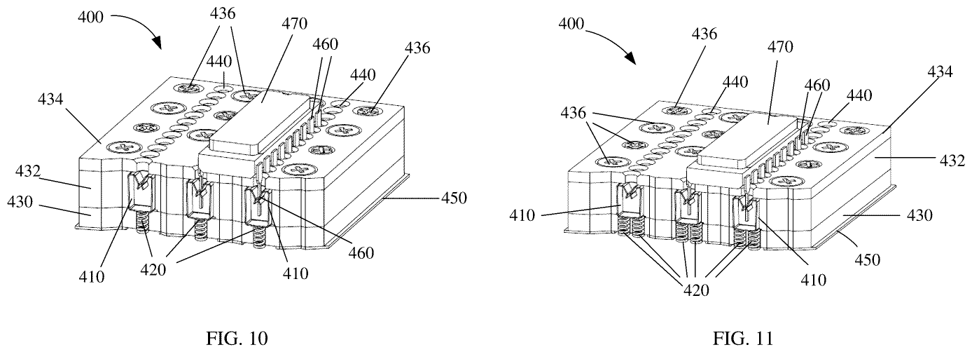

As illustrated in the embodiments of a test socket assembly 400 shown in FIGS. 10 and 11, the socket body includes three stacked socket plates 430, 432, 434 held together by screws 436. FIG. 9A is a perspective view of the middle socket plate 432. A spring contact receptacle 410 is inserted into each cavity 412 in the middle socket plate 432 such that the contacts 416 are oriented to be at the top (close to the top socket plate 434) of the socket and the wide flat bottom is oriented to be at the bottom (close to the bottom socket plate 430, as shown in FIGS. 10 and 11. The socket plates 430, 432, 434 may be manufactured from ceramics or hard-anodized aluminum parts, or a combination of ceramics and hard-anodized aluminum part. In the illustrated embodiment, the test socket assembly 400 includes three socket plates 430, 432, 434 that are held together by multiple screws 436 threaded through openings 438 in the socket plates 430, 432, 434. It will be understood that the openings 438 in each of the socket plates 430, 432, 434 are aligned with the openings 438 in the other socket plates 430, 432, 434 so that screws 436 can be threaded through each of the socket plates 430, 432, 434 when they are stacked to form the test socket assembly 400. It will be understood that although three socket plates are described in the illustrated embodiment, it is possible to have more or fewer socket plates in other embodiments. For example, the top plate and middle plate can be formed as a single plate.

As shown in FIG. 10, and 11, there are multiple openings 440 in the top socket plate 434. These openings 440 are aligned with the spring contact receptacles 410 such that the contacts 416 of each spring contact receptacle 410 are below the opening 440. As shown in FIGS. 10 and 11, a contact pin 460 from a test package 470 can be inserted through the opening 440 and received through between the contacts 416, as shown in FIGS. 10 and 11.

According to an embodiment of a test socket assembly 400, the conventional non-ZIF socket pin receptacle design (shell and internal small clip) is replaced by a spring contact receptacle 410 having a one-piece design, as shown in FIGS. 8A-8C. The spring contact receptacle 410 is formed from a flat spring material that is stamped and formed into the one-piece design shown in FIGS. 8A-8C. It will be noted that the one-piece design improves reliability of the spring contact receptacle 410, which is formed of high temperature spring material that is rated and heat-treated to 450° C. Suitable materials for the spring contact receptacle 410 include spring materials with high corrosion and oxidation resistance at high temperatures above 500° C.; a particularly suitable material for the spring contact receptacle 410 is Inconel x750. The high corrosion and oxidation heat resistance of the material eliminates at least one known primary source of material and electrical degradation. In an embodiment, the thickness t of the spring material is about 0.005 inch, the height h of the spring contact receptacle 410 is 0.173 inch, the length l of the spring contact receptacle 410 is 0.122 inch, and the width w of the spring contact receptacle 410 is 0.067 inch. It will be understood that the thickness t of the spring material can be in a range from 40% thinner to 40% thicker than 0.005 inch, 0.003 inch-0.007 inch. It will be understood that the basic mechanical shape of the spring contact receptacle 410 can be altered to satisfy certain design constraints, such as test device pin pitch, socket height, etc. The thickness of the material of the spring contact receptacle 410 can also be changed, if necessary. The skilled artisan will understand, for example, that a thicker material will provide a stronger spring force requiring higher test device insertion and extraction forces. Conversely, a thinner material will provide weaker spring force causing less stable electrical contact.

As shown in the front view of FIG. 8B, the spring contact receptacle 410 has a generally rectangular U-shape with an open top. The base 414 of the spring contact receptacle is a flat, horizontal portion. The flat base 414 may be attached directly to a SMT pad 440 on a DUT board 480 using solder alloys. With this method, the maximum temperature rating of the DUT Board is dictated by the type of PCB (phenolic or ceramic thick-film type) and by the temperature rating of the solder.

Two substantially vertical walls 418 extend upwards from the base 414. In the illustrated embodiment, the walls 418 extend at an angle α of 92° from the base 414 such that the walls 418 flare slightly outward. Each of the top walls 419 of the spring contact receptacle 410 extends substantially horizontally inward from the walls 418 about halfway to the center of the spring contact receptacle 410 and slope downward at an angle β of 121° toward the center until they almost touch another, with 0.10-0.15 inch separating them at the closest point to form the contacts 416, as shown in FIGS. 8A and 8B. At the contacts 416, the walls then extend back toward the walls 418 at an angle γ of 139°. In the illustrated embodiment, each of the top walls 419 is oriented at an angle Θ of 90° from the wall 418 from which it extends. It will be understood that these dimensions, angles, and ranges can vary in other embodiments, and that they are a compromise resulting from the material thickness and width of the spring contact receptacle 410, socket 400 height, thickness of the top socket plate 434, to obtain an optimal electrical contact point from the test package pin 460 to the contact receptacle contacts 416.

FIGS. 8A and 8B show the spring contact receptacle 410 as it is manufactured, not as it is installed in the socket assembly 400. The spring contact receptacle 410 is manufactured so that its contacts 416 remain slightly open (not in contact with one another) at the top of the spring contact receptacle 410, but when installed into the cavity 412 in the socket plate 432, the contacts 416 close such that they may be in contact with one another, to provide the proper insertion and extraction forces needed for the leads (pins) 460 of the test package 470. Typically, a pin 460 of a standard test package 470 is 0.018 inch wide and 0.010 inch thick. The insertion and extraction force for spring contact receptacle 410 is about 200 grams per contact. It will be understood that the slight outward flare of the vertical walls 418 cause the contacts 416 to be spaced apart from one another. When the spring contact receptacle 410 is installed into the opening 412, the spring material causes the spring contact receptacle 410 to conform to the shape of the opening 412 (walls 418 are orthogonal to flat bottom 414) and the contacts 416 move toward one another such that they may be in contact when installed in the test socket assembly 400. It will be noted that having the contacts 416 slightly open serves two primary purposes: 1) allows proper gold-plating of the electrical contact surfaces and 2) aids in socket assembly by retaining all spring contact receptacles 410 in place in the middle plate 432 by a slight spring tension of all contact receptacles 410 until the socket is fully assembled, thereby allowing for mass pre-assembly of the middle plate 432.

The pin 460 extending from a test package 470 is inserted through an opening 440 on the top side of the top socket plate 434 and between the two contact areas 416 of the spring contact receptacle 410. As shown in FIGS. 8A and 8B, the two contact areas 416 look like back to back > < symbols. The one-piece spring contact receptacle 410 is a spring mechanism designed to keep constant pressure against the test package pin 460, as described in more detail below.

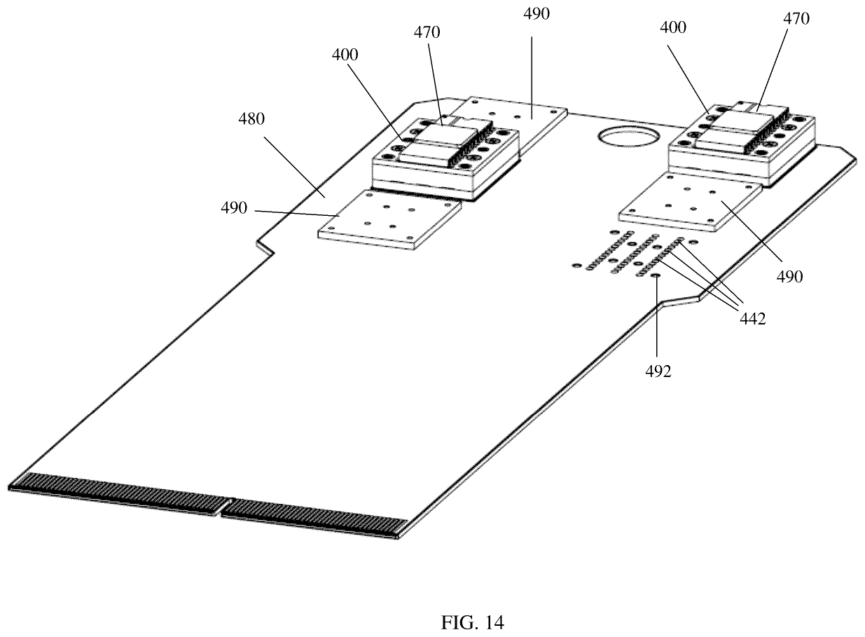

It will be noted that the substantially rectangular shape of the spring contact receptacle 410 is optimized to reduce movement of the spring contact receptacle 410 to minimize damage of the part. When the spring contact receptacle 410 is installed in the test socket assembly 400, it is housed in a matching rectangular cavity 412 with the walls 418 of the spring contact receptacle 410 abutting the walls of the cavity 412. As shown in FIGS. 10 and 11, at least a portion of the top walls 419 also abuts the bottom of the top socket plate 434 and the base 414 is in contact with at least one compression spring 420 below. Thus, only very little vertical movement is allowed to compensate for the manufacturing tolerances of the spring contact receptacle 410 and other parts of the test socket assembly 400 as well as the spring material's coefficients of thermal linear expansion and contraction at test temperature. The spring material is preferably a high corrosion and oxidation resistance high temperature spring material, which can be gold plated for maximum corrosion resistance and electrical performance. The constrictive design of the spring contact receptacle 410 and the socket assembly 400 in which it is installed reduces the possibility of electrical contact failures due to breakage of contact between the spring contact receptacle 410 and the coiled springs 420, and from the coiled springs 420 to the PCB pads 442 (shown in FIG. 14). It will be noted that an electrical insulator 450 is positioned underneath each test socket assembly 400 (between the test socket assembly 400 and DUT board 480) and that the electrical insulator 450 has cutouts underneath each compression spring(s) 420 to allow the compression springs 420 to contact the pads 442 on the DUT board 480.

The flat spring material minimizes the spring contact receptacle's 410 electrical resistance, while providing maximum electrical contact area at its contacts 416 to two sides of each test package lead (pin) 460, as shown in FIGS. 10 and 11. The minimized electrical resistance allows more current to flow through the spring contact receptacle 410 for a given voltage. The spring contact receptacle's 410 two wide-and-flat contact areas 416 rest against the wider portion of the rectangular shaped pin 460 of the test package 470. This ensures the maximum possible electrical contact area is used for lowest possible electrical resistance (and maximum test current). This feature is also beneficial for ultra-low voltage measuring applications. It will be noted that the socket assembly 400 may also accept test packages 470 with round pins having a diameter of about 0.015 inch+/−0.005 inch.

The design of the spring contact receptacle 410 features a wide flat bottom 414 to allow for increased contact with one or more compression (coiled) springs 420 underneath the spring contact receptacle 410. If the desired test current is greater than 1 amp, two springs 420 can be provided underneath the spring contact receptacle 410. The wide flat bottom 414 also ensures maximum and stable electrical contact from the DUT board pads 442 through the spring(s) 420 to the spring contact receptacle 410. In some embodiments, the flat bottom 414 may be used to attach directly to surface mount device pads (SMD) 442 using solder alloys. With this method, the DUT board's 480 maximum temperature rating is dictated by the type of PCB (can be phenolic or ceramic thick-film type) and by the temperature rating of the solder.

The shape of the spring contact receptacle 410 is optimized for maximum electrical contact areas and lowest electrical resistance. According to a preferred embodiment, the material and thickness of the spring contact receptacle are selected for practical manufacturing at lowest cost, while maximizing its test current and temperature ratings. According to some embodiments, the spring contact receptacle 410 can be formed from alloys commonly used for high temperature electrical contacts and springs, such as Inconel x750 (nickel-chromium). Other suitable materials for the spring contact receptacle 410 include nickel-chromium, cobalt-nickel, stainless steel, cobalt-chromium-nickel, nickel-iron, nickel-iron-cobalt, nickel-copper, and titanium. In an embodiment, the spring contact receptacle 410 is gold-plated to reduce corrosion build-up at high temperatures and for optimal electrical contact.

The spring contact receptacle 410 is designed to support low DUT resistance for high test current at high temperature applications. This innovative design of a test socket assembly 400 incorporating spring contact receptacles 410 supports DC test currents up to 2 amps per pin at temperatures up to 450° C.

The spring contact receptacle 410 also provides a self-cleaning contact feature when a test package 470 is inserted into the socket assembly. As noted above, the contacts 416 are in contact with one another in the test socket assembly 400, which not only provides the need for insertion and extraction forces, but also provides self-cleaning each time a test package 470 is inserted into the socket assembly 400. The insertion and removal of the test package 470 from the socket assembly 400 also serves to self-clean all the electrical contacts 416 as well as the pins 460 of the test package 470.

The spring contact receptacle 410 provides improved performance and reliability of connectivity for sockets with built-in resistive temperature device (RTD) sensors. RTD wire leads could be brazed (welded) directly to a flat area on the new receptacle.

FIG. 9B is a perspective view of an embodiment of the top socket plate 434. In the embodiment shown in FIGS. 9A and 9B, there are three rows of rectangular shaped cavities 412 in the middle socket plate 432 and there are three corresponding rows of openings 440 in the top socket plate 434. According to an embodiment, there are 14 rectangular shaped cavities 412 in each row and 14 openings 440 in each row on the bottom socket plate 430 and top socket plate 434, respectively. The illustrated embodiment of the socket assembly 400 is intended for use with a 28 pin test package 470 having two rows of contact pins 460, with each row having 14 contact pins 460. It will be understood that in FIGS. 10-12, the test package 470 is a CERDIP 100.

FIGS. 9C and 9D are perspective views of embodiments of a bottom socket plate 430 of the test socket assembly 400. As shown in FIG. 9C, the bottom socket plate 430 has three rows of openings 416. In the embodiment shown in FIG. 9C, there are 14 openings in each of the three rows. The embodiment of the bottom socket plate 430 shown in FIG. 9D has three rows of pairs of openings 416. In the embodiment shown in FIG. 9D, there are 28 openings in each of the three rows. It will be understood that the rows of openings 416 align with the cavities 412 in the middle socket plate 432 and the openings 440 in the top socket plate 434. Each of the openings 416 can accommodate a compression spring 420. As noted above, the spring contact receptacles 410 are installed into rectangular shaped cavities 412 in the middle socket plate 432, oriented such that the contacts 416 are positioned to be near the top of the test socket assembly 400 and the flat bottom 414 is positioned closer to the bottom of the socket 400 to contact one or more compression springs 420 in the bottom socket plate 430. The socket 400 provides mechanical stability, easy assembly, and provides maximum electrical insulation between pins. According to some embodiments, the socket plates 430, 432, 434 may be constructed from ceramics or hard anodized aluminum.

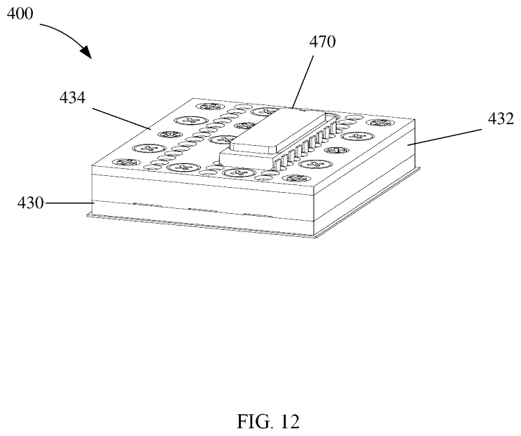

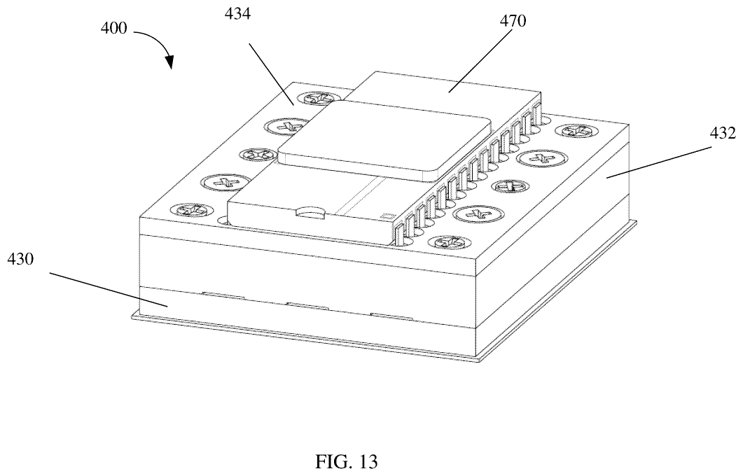

FIGS. 10 AND 11 show cut-out views of two embodiments of the socket assembly 400. As shown in FIG. 10, each spring contact receptacle 410 is in contact with one compression spring 420. In the embodiment shown in FIG. 11, each spring contact receptacle 410 contacts two compression springs 420. In the embodiment shown in FIG. 10, one compression spring 420 is provided for lower current applications (up to 1 amp). In the embodiment shown in FIG. 11, two compression springs 420 are provided for higher current applications (1 to 2.5 amps). FIG. 12 shows a perspective view of an embodiment of the socket 400 with a test package 470 inserted. In FIG. 12 the test package 470 is a CERDIP package and FIG. 13 is a perspective view of the test socket assembly 400 where the test package 470 that is inserted is a SIDEBRAZE 110 package.

As shown in FIG. 12, the exterior of the test socket assembly 400 is similar to traditional non-ZIF sockets, such as the one shown in FIG. 5. It will be noted that the socket assembly 400 is simple to repair by replacing components, such as the spring contact receptacles 410 and the compression springs 420. It will be understood that other types of springs, such as flat wire, helical, conical, Belleville, wave, finger, etc. springs, may be used in place of compression springs.

FIG. 14 is a view of a DUT board 480 with multiple test socket assemblies 400 attached. It will be understood that test socket assemblies 400 may be attached on both sides of the DUT board 480. In FIG. 14, only the test socket assemblies 400 attached to the top side of the DUT board 480 are shown. Since the DUT board 480 is a surface mount (SMT) type board, a nut plate 490 is used to attach the test socket assembly 400 to the DUT board 480. For each test socket assembly 400, a nut plate 490 is positioned on the opposite side of the DUT board 480. The nut plate 490 has multiple openings that align with some of the openings 438 in the bottom socket plate 430 to allow a screw or other fastener to attach the test socket assembly 400 (and the nut plate 490) to the DUT board 480. According to an embodiment, the nut plate 490 is a metal plate with threaded holes used for securing the socket assembly 400 to the DUT board 480. It will be understood that multiple nut plates 490 are shown in FIG. 14 and that for each of these nut plates 490, a test socket assembly 400 is on the opposite side of the DUT board 480. It will be understood that the holes in the nut plate 490 are aligned with a set of corresponding holes 492 in the DUT board 480 to secure the nut plate 490 and test socket assembly 400 to the DUT board 480.

The embodiments of the test socket assemblies 400 described herein have a compact design that allows for minimum test socket footprint area and height. The compact design also allows for maximum test socket density per DUT board 480 and also allows test socket assemblies 400 to have rows for 0.300″ and/or 0.600″ wide test DIP packages 470. It will be understood that the test socket assemblies 400 can be manufactured for any DIP package pin count. The test socket assemblies 400 described herein are also easy to repair because soldered or molded parts are not necessary. The test socket assemblies 400 can be easily repaired by replacing individual damaged components, such as the spring contact receptacles 410 and the compression springs 420.

It will be noted that different embodiments of the test socket assembly 400 may have different socket configurations having different pin counts, row spacing, pitch between spring contact receptacles, etc. The test socket assembly can be installed on high temperature ceramic PCB based boards using solder-less methods (mount over springs) or installed on lower temperature PCB boards using traditional solder alloys (SMT methods).

Although only a few embodiments of the invention have been described in detail, it should be appreciated that the invention may be implemented in many other forms without departing from the spirit or scope of the invention. In view of all of the foregoing, it should be apparent that the present embodiments are illustrative and not restrictive and the invention is not limited to the details given herein, but may be modified within the scope and equivalents of the appended claims.

What is claimed is:

1. A test socket assembly for use in testing a packaged integrated circuit device having a plurality of pins extending therefrom, the test socket assembly comprising:
a first member for receiving an integrated circuit test package and having a plurality of openings for receiving pins extending from the test package;
a plurality of one-piece spring contact receptacles, wherein each of the one-piece spring contact receptacles is positioned under an opening to receive a pin extending from the test package; and
a plurality of compression springs, wherein each of the one-piece spring contact receptacles is positioned over at least one compression spring, and wherein the test socket assembly can operate reliably at temperatures greater than 350° C and at test currents greater than 1 amp DC per pin.

2. The test socket assembly of claim 1, wherein the test socket assembly operates reliably at test currents up to 2 amps DC per pin and at temperatures up to 450° C.

3. The test socket assembly of claim 1, wherein each one-piece spring contact receptacle is positioned over two compression springs.

4. The test socket assembly of claim 1, wherein the test socket assembly operates reliably at test currents up to 2.5 amps DC per pin and at temperatures up to 350° C.

5. The test socket assembly of claim 1, wherein each one-piece spring contact receptacle is stamped and formed from a flat sheet of spring material having a thickness in a range of about 0.003 inch-0.007 inch.

6. The test socket assembly of claim 5, wherein each of the one-piece spring contact receptacles is stamped and formed into a substantially rectangular U-shape with two contact areas configured to receive a pin inserted therebetween and maintain constant pressure against the pin.

7. The test socket assembly of claim 6, wherein each of the one-piece spring contact receptacles has a flat wide base in contact with at least one compression spring.

8. The test socket assembly of claim 6, wherein the two contact areas abut one another.

9. The test socket assembly of claim 7, wherein each of the contact areas is connected with the flat wide base by a substantially vertical wall extending therebetween.

10. The test socket assembly of claim 6, the two contact areas are positioned below an opening in the first member.

11. The test socket assembly of claim 1, wherein the first member is a ceramic plate.

12. The test socket assembly of claim 11, wherein a plurality of packaged devices can be inserted therein.

13. The test socket assembly of claim 1, wherein each one-piece spring contact receptacle is gold plated.

14. A test socket assembly for use in testing a packaged integrated circuit device having a plurality of pins extending therefrom, the test socket assembly comprising:
a first member for receiving an integrated circuit test package and having a plurality of openings configured to receive pins extending from the test package;
a second member stacked below the first member;
a third member stacked below the second member;
a plurality of one-piece spring contact receptacles, wherein each of the one-piece spring contact receptacles is positioned in the second member under an opening of the first member to receive a pin extending from the test package;
a plurality of compression springs, wherein each of the one-piece spring contact receptacles is positioned over at least one compression spring, and wherein each of the compression springs is positioned in the third member; and
wherein the test socket assembly can operate reliably at temperatures greater than 350° C and at test currents greater than 1 amp DC per pin.

15. The test socket assembly of claim 14, wherein the one-piece spring contact receptacle is a flat spring material that is stamped and formed into a substantially rectangular U-shape with two contact areas configured to receive a pin inserted therebetween and maintain constant pressure against the pin.

16. The test socket assembly of claim 15, wherein the flat spring material is selected from the group consisting of: nickel-chromium, cobalt-nickel, stainless steel, cobalt-chromium-nickel, nickel-iron, nickel-iron-cobalt, nickel-copper, and titanium.

17. The test socket assembly of claim 16, wherein the flat spring material is gold plated.

18. The test socket assembly of claim 14, wherein the openings in the first member are arranged in parallel rows for receiving pins from a dual in-line integrated circuit package.

19. The test socket assembly of claim 14, wherein the first, second, and third members comprise at least one of ceramic and hard-anodized aluminum.
